(19) United States
(12) Patent Application Publication
(10) Pub. No.: US 2009/0159980 A1
(43) Pub. Date: Jun. 25, 2009

(54) Semiconductor Device and Method of Fabricating the Same

(76) Inventor: Dae Kyeun Kim, Yongin-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/337,511

(22) Filed: Dec. 17, 2008

(30) Foreign Application Priority Data
Dec. 24, 2007 (KR) 10-2007-0136088

(51) Int. Cl. H01L 21/762; H01L 27/092

(52) U.S. Cl. 257/369; 438/424; 257/E27.062; 257/E21.546

(57) ABSTRACT

A semiconductor device and a method of fabricating the same are disclosed. The semiconductor device includes a conductive well formed by implanting a first conductive impurity into a semiconductor substrate, a device isolation film on one side of the conductive well, and an insulating region below the device isolation film and including the first conductive impurity and a second conductive impurity. The semiconductor device has the insulating region below the device isolation film, making it possible to prevent a short circuit generated between devices.

### CROSS-REFERENCE TO RELATED APPLICATIONS

The present application claims priority under 35 U.S.C. 119 to Korean Patent Application No. 10-2007-0136088 (filed on Dec. 24, 2007), which is hereby incorporated by reference in its entirety.

### FIELD OF THE INVENTION

The embodiment relates to a semiconductor device and a method of fabricating the same.

### DESCRIPTION OF THE RELATED ART

With the development of information processing techniques, there has been a demand for high density and highly integrated semiconductor chips. Accordingly, it is important to make intervals or spaces between semiconductor devices on such chips narrow, but to prevent a short circuit which may occur between the semiconductor devices.

### SUMMARY

Embodiments of the invention provide a semiconductor device which prevents a short circuit between adjacent semiconductor devices.

Embodiments of the invention relate to a semiconductor device comprising a conductive well comprising (and which may be formed by implanting) a first conductive impurity in a semiconductor substrate; a device isolation film on one side of the conductive well; and an insulating region below the device isolation film and including the first conductive impurity and a second conductive impurity.

Other embodiments relate to a method of fabricating a semiconductor device comprising forming a trench on/in a semiconductor substrate; forming an insulating region including a first conductive impurity and a second conductive material on an inner side or exposed surface of the trench; and filling the trench with an insulating material.

The semiconductor device according to various embodiments is insulated and/or isolated from other (e.g., adjacent) semiconductor devices by a device isolation film and an insulating region below the device isolation film. Therefore, the present semiconductor device can prevent a short circuit between it and an adjacent semiconductor device more efficiently, as compared to the case when a semiconductor device is insulated only by the device isolation film.

### BRIEF DESCRIPTION OF THE DRAWINGS

FIG. 1 is a cross-sectional view showing an exemplary CMOS transistor according to embodiments of the invention.

FIGS. 2A to 2E are cross-sectional views showing exemplary processes for a method of fabricating a semiconductor device.

### DETAILED DESCRIPTION OF THE EMBODIMENTS

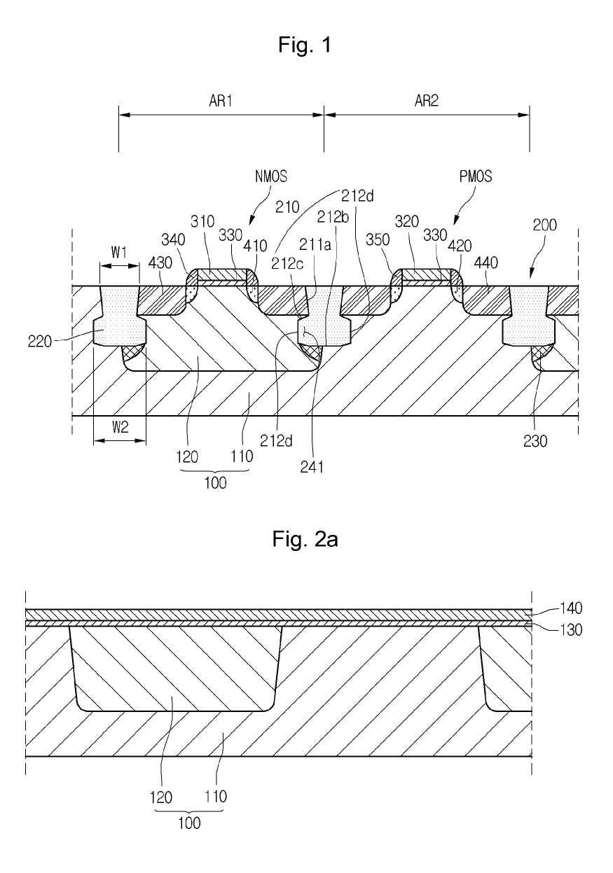

FIG. 1 is a cross-sectional view showing an exemplary CMOS transistor according to an embodiment of the invention.

Referring to FIG. 1, the CMOS transistor includes a semiconductor substrate 100, a device isolation film 200, an insulating region 230, a NMOS transistor NMOS and a PMOS transistor PMOS.

The semiconductor substrate may have a plate shape. As the semiconductor substrate 100, a material such as single crystal silicon and the like may be exemplified. The semiconductor substrate 100 includes a region 110 including a low concentration of an n type impurity and a p type well 120 including a low concentration of a p type impurity.

The device isolation film 200 is formed on at least one side of the p-type well 120. Preferably, the device isolation film 200 surrounds the p type well 120 at the interface between the p-type well and the n-type region 110, viewing the device in a layout view. The device isolation film 200 includes a trench 210 and an insulating film 220.

The trench 210 includes a first side wall 211a and second side wall 212c angled (e.g., bent or slightly bent) away from the first side wall 211a. The first side wall 211a generally has flat or planar side walls. The flat side walls 211a face each other by way of example. The first side wall 211a may be sloped (e.g., bent or slightly bent) from the top surface of the semiconductor substrate 100. In other words, the side wall 211a may have an angle other than 90° (e.g., from 80° to 89°) with respect to the planar upper surface of the semiconductor substrate.

The second sidewall 212c is angled (e.g., bent or slightly bent) from the first side wall 211a. At this time, the trench 210 may include a third side wall 212d which is angled (e.g., bent or slightly bent) from the second side wall 212c.

Also, the trench 210 includes a bottom surface 212b which is angled (e.g., bent or slightly bent) from the third side wall 212d. At this time, a groove, hole, extension or reservoir (hereinafter “groove”) is formed by the second side wall 212c, the third side wall 212d and the bottom surface 212b, wherein the width W1 of the bottom surface 212b may be larger than the width W2 of inlet of the trench 210.

The insulating film 220 is disposed on the inner side of the trench 210. More specifically, the trench 210 is filled with the insulating film 220. As the insulating film 220, materials such as oxides (e.g., silicon dioxide) may be exemplified, and the insulating film 220 has a projection or extension (hereinafter “projection”) 241 corresponding to the groove.

The semiconductor substrate 100 is divided into a first active region AR1 and a second active region AR2 by the device isolation film 200. At this time, the p-type well 120 is formed in the first active region AR1.

The insulating region 230 is formed below the device isolation film 220 and may be formed adjacent to the device isolation film 200. Also, the insulating region 230 is formed to be adjacent to the p-type well 120.

The insulating region 230 includes both a p type impurity and an n type impurity. The concentration of the p-type impurity and the concentration of the n-type impurity included in the insulating region 230 are substantially the same. Also, the concentration of the p-type impurity included in the insulating region 230 is substantially the same as the concentration of the p-type impurity included in the p-type well 120. Therefore, the resistance in the insulating region 230 is higher than that in the p-type well 120.

The NMOS transistor NMOS is formed in the first active region AR1. The NMOS transistor NMOS includes a first gate electrode 310, first spacers 340, n-type LDD regions 410, and n+ type source/drain regions 430.

The first gate electrode 310 is formed on the p-type well 120. As the first gate electrode 310, materials such as polysilicon, metal, a metal silicide or the like may be exemplified. Also, a gate insulating film 220 is between the first gate electrode 310 and the semiconductor substrate 100, insulating the first gate electrode from the semiconductor substrate 100. The gate insulating film 220 may comprise a thermal oxide (e.g., silicon dioxide, formed by wet or dry thermal oxidation).

The first spacer 340 is disposed on a side wall of the first gate electrode 310. As the spacer 340, materials such as oxides, nitrides or the like (e.g., a silicon nitride-on-silicon dioxide bilayer) may be exemplified, and the first spacer 340 insulates the side wall of the first gate electrode 310.

The n-type LDD region 410 is disposed below the first spacer 340. The pair of n-type LDD regions 410, which include a low concentration of n type impurity (such as P, As, or Sb), are spaced from each other.

The n+ type source/drain region 430 is formed on one side or on opposite sides of the first gate electrode 310. The n+ type source/drain region 430 is adjacent to the n-type LDD region 410.

The PMOS transistor PMOS is formed in the second active region AR2. The PMOS transistor PMOS includes a second gate electrode 320, second spacers 350, p-type LDD regions 420, and p+ type source/drain regions 440.

The second gate electrode 320 is formed on the region including the n type impurity. As the second gate electrode 320, materials such as polysilicon, metal, a metal silicide or the like may be exemplified.

Also, a gate insulating film 220 is between the second gate electrode 320 and the semiconductor substrate 100, insulating the second gate electrode from the semiconductor substrate 100. The gate insulating film 220 may comprise a thermal oxide (e.g., silicon dioxide, formed by wet or dry thermal oxidation).

The second spacer 350 is disposed on a side wall of the second gate electrode 320. As the second spacer 350, material such as oxides, nitrides or the like (e.g., a silicon nitride-on-silicon dioxide bilayer) may be exemplified, and the second spacer 350 insulates the side wall of the second gate electrode 350.

The p-type LDD region 420 is disposed below the second spacer 350. The pair of p-type LDD regions 420, which include a low concentration of a p type impurity (such as B), are spaced from each other.

The p+ type source/drain region 440 is formed on one side of the second gate electrode 320. The p+ type source/drain region 440 is adjacent to the p-type LDD region 420.

The NMOS transistor NMOS and the PMOS transistor PMOS are isolated and/or insulated by the device isolation film 200 and the insulating region 230.

At this time, the insulating film 220 includes a projection or extension 241 that extends laterally so that the path on which current flows from the NMOS transistor NMOS to the PMOS transistor PMOS is the same. In other words, compared with the case when the insulating film 220 does not include the projection 241, the path on which current flows between the two transistors lengths further by the device isolation film 200, making it possible to prevent a short circuit which may be generated between the two transistors.

Also, the resistance in the insulating region 230 is higher than that in the p-type well 120. Therefore, a short circuit which may be generated between the two transistors is prevented by the insulating region 230.

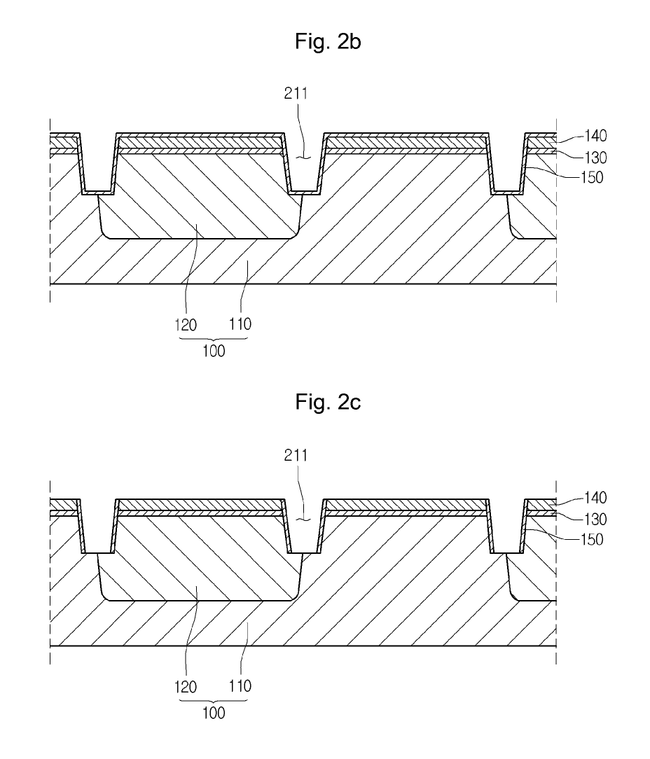

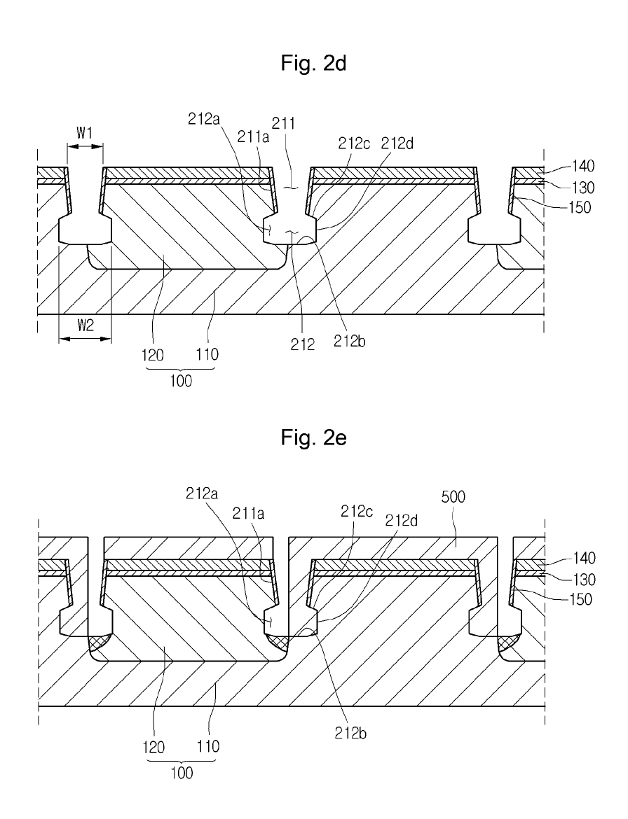

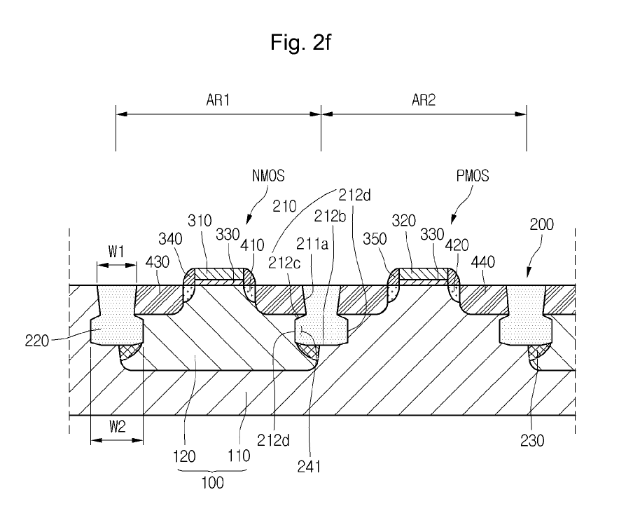

FIGS. 2A to 2F are cross-sectional views showing processes of an exemplary method of fabricating a semiconductor device.

Referring to FIG. 2A, a low concentration of a p type impurity is implanted selectively into a silicon substrate including a low concentration of an n type impurity (e.g., a lower concentration than that of the p type impurity) to form a p-type well 120. Thereby, a semiconductor substrate 100 which includes a region 110 including an n type impurity and the p-type well 120 is formed.

Thereafter, a thermal oxidation process or a chemical vapor deposition process is performed on the semiconductor substrate 100 to form an oxide film 130 (e.g., silicon dioxide), and a nitride film 140 (e.g., silicon nitride) is formed on the oxide film 130 using the chemical vapor deposition (CVD).

Referring to FIG. 2B, after the nitride film 140 is formed, the nitride film 140, the oxide film 130 and the semiconductor substrate 100 are selectively etched to form a first trench 211. The first trench 211 is formed between the p-type well 120 and the region 110 including the n type impurity.

Thereafter, a protective film 150 is formed on the inner side of the first trench 211 and on the nitride film 140 using a chemical vapor deposition process. The protective film 140 may comprise silicon oxide, silicon nitride, and/or silicon oxynitride.

The first trench 211 includes a first side wall 211a extending from a top surface of the semiconductor substrate 100. The trench 211 comprises two (or four) flat side walls 211a, where opposing flat side walls face each other.

Referring to FIG. 2C, the protective film 150 formed on the nitride film 140 and the protective film 150 disposed on the bottom surface of the first trench 211 are removed using an isotropic etching process, and the protective film 150 remains on only the side wall 211a of the first trench 211.

Referring to FIG. 2D, the semiconductor substrate 100 below the first trench 211 is etched using an anisotropic etching process (e.g., wet etching using a liquid-phase etchant that selectively etches silicon), and a second trench 212 is formed below the first trench 211.

The second trench 212 includes a bottom surface 212b and a groove or extension 212a formed laterally from the flat side walls 211a of the first trench 211.

At this time, the width of the second trench 212 may be larger than that of the first trench 211. For example, the first trench 211 may be tapered, and at this time, the width W2 of the second trench 212 may be larger than the largest width W1 of the first trench 211.

As described above, a trench 210 including the first trench 211 and second trench 212 is formed.

Referring to FIG. 2e, after the trench 210 is formed, a photoresist pattern 500 is formed on the semiconductor substrate 100 and then an n type impurity is implanted into a portion of the p-type well 120 using the photoresist pattern 500 as a mask, forming an insulating region 230.

At this time, the concentration of n type impurity implanted is substantially the same as the concentration of p type impurity implanted into the p-type well 120. Therefore, the resistance of the insulating region 230 is higher than the resistance of the p-type well 120 or the resistance of the region 110 having where the n type impurity therein.

Referring to FIG. 2F, the photoresist pattern 500 is removed and the trench 210 is filled with oxide (e.g., silicon dioxide, by CVD, plasma-enhanced CVD, or high density plasma CVD), forming an insulating film 200. Thereby, a device isolation film 200 including the trench 210 and the insulating film 200 is formed, and the semiconductor substrate 100 is divided into a first active region AR1 and a second active region AR2.

Thereafter, after the nitride film 140 is removed and a polysilicon layer is formed on the semiconductor substrate 100 (e.g., by CVD). The polysilicon layer and the oxide film 130 are patterned, forming a first gate electrode 310 and a second gate electrode 320. Optionally, nitride film 140 and oxide film 130 are removed, and a thermal oxide layer is formed as the gate insulating layer, the polysilicon layer is formed thereon prior to patterning the polysilicon layer and the gate insulating layer to form the gate electrodes 310 and 320 and the gate insulator 330.

Thereafter, a low concentration of an n type impurity is selectively implanted into the first active region AR1 to form a n-type LDD region 410 (e.g., after masking PMOS transistor PMOS with a patterned photoresist), and a low concentration p type impurity is selectively implanted into the second active region AR2 to form a p-type LDD region 420 (e.g., after masking the NMOS transistor NMOS with a patterned photoresist).

Thereafter, a thin nitride film is formed (optionally after forming a thin oxide layer) over the semiconductor substrate 100 and an anisotropic etching process such as an etch-back is performed, forming a first spacer 340 and a second spacer 350.

Thereafter, the PMOS transistor region PMOS is masked with a photoresist pattern, and a high concentration of an n type impurity is implanted into the first active region AR1 using the first gate electrode and first spacer 340 as a mask to form an n+ type source/drain region 430, thereby forming a NMOS transistor NMOS.

Also, the NMOS transistor region NMOS is masked with a photoresist pattern, and a high concentration of a p type impurity is implanted into the second active region AR2 using the second gate electrode and second spacer 350 as a mask to form p+ type source/drain region 430, thereby forming a PMOS transistor PMOS.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a conductive well comprising a first conductive type impurity in a semiconductor substrate;
a device isolation film on one side of the conductive well; and
an insulating region below the device isolation film, including the first conductive type impurity and a second conductive type impurity.

2. The semiconductor device according to claim 1, wherein a concentration of the first conductive type impurity and a concentration of the second conductive impurity in the insulating region are substantially identical.

3. The semiconductor device according to claim 1, wherein the device isolation film includes a trench with a groove in and an inner side wall an insulating material to be filled in the inner side of the trench.

4. The semiconductor device according to claim 3, wherein the trench includes first side walls facing each other and second side walls angled from the first side walls.

5. The semiconductor device according to claim 4, wherein the trench includes a bottom surface, and a width of the bottom surface is greater than that of an opening of the trench.

6. The semiconductor device according to claim 1, wherein the device isolation film is over an entire vertical interface between the conductive well and the substrate, the substrate including a second conductive type impurity.

7. The semiconductor device according to claim 6, wherein the insulating region is entirely within a portion of the conductive well below device isolation film.

8. The semiconductor device according to claim 1, wherein the first conductive type impurity is an n type impurity.

9. The semiconductor device according to claim 8, wherein the second conductive type impurity is a p type impurity.

10. The semiconductor device according to claim 1, further comprising an NMOS transistor on the conductive well.

11. The semiconductor device according to claim 10, further comprising a PMOS transistor on the substrate in an active region adjacent to the device isolation.

12. The semiconductor device according to claim 11, wherein each of the NMOS transistor and the PMOS transistor comprises a gate electrode on a gate insulating layer, a spacer on a sidewall of the gate electrode, and n-type LDD regions and n+ type source/drain regions on opposite sides of the gate electrode.

13. A method of fabricating a semiconductor device comprising:
forming a trench in a semiconductor substrate;
forming an insulating region including a first conductive type impurity and a second conductive type impurity below the trench; and
filling the trench with an insulating material.

14. The method according to claim 13, wherein forming the trench includes:
forming a first trench by selectively etching the semiconductor substrate; and
forming a second trench which includes a lateral groove in the first trench by etching an inner surface of the first trench.

15. The method according to claim 14, wherein forming the second trench further includes:
forming a protective film on inner surfaces of the first trench;
removing a portion of the protective film; and
etching an exposed inner surface of the first trench using a remaining portion of the protective film as a mask.

16. The method according to claim 15, wherein the trench includes first side walls facing each other, second side walls angled away from the first side walls, and a bottom surface, the bottom surface having a width that is greater than that of an opening of the first trench.

17. The method according to claim 16, wherein etching the exposed inner surface of the first trench comprises wet etching.

18. The method according to claim 14, further comprising depositing a device isolation film in the trench.

19. The method according to claim 13, wherein forming the insulating region includes:
forming a conductive well by implanting the first conductive type impurity into the semiconductor substrate; and
forming the insulating region by implanting the second conductive impurity into a portion of the conductive well.

20. The method according to claim 19, wherein the second conductive type impurity has a concentration corresponding to or substantially equal to a concentration of the first conductive type impurity in the conductive well.
